(19) United States
(12) Patent Application Publication
(10) Pub. No.: US 2015/0137286 A1
(43) Pub. Date: May 21, 2015

(54) METHOD TO FORM MRAM BY DUAL ION IMPLANTATION

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/289,648

(22) Filed: May 29, 2014

Related U.S. Application Data
(60) Provisional application No. 61/829,250, filed on May 31, 2013.

(51) Int. Cl. H01L 43/02; H01L 43/08; H01L 43/12; H01L 43/10

(52) U.S. Cl. CPC H01L 43/02; H01L 43/10; H01L 43/08; H01L 43/12
USPC 257/421; 438/3

(57) ABSTRACT

A method to form small magnetic random access memory (MRAM) by dual ion implantation is provided. The first ion implantation add oxygen-gettering material surrounding the photo mask opened areas including sidewall followed by oxygen ion implantation to fully oxidize these oxygen-getter implanted areas into an electrically insulating layers to avoid current shunting during memory read/write time, and thus maximizing the tunneling magnetic resistance (TMR) signal. Such method is effective to repair the magnetic dead (weak or non magnetic but electrically conducting) layer on the sidewall.

### RELATED APPLICATIONS

This application claims the priority benefit of U.S. Provisional Application No. 61,829,250 filed on May 31, 2013, which is incorporated herein by reference.

### BACKGROUND OF THE INVENTION

1. Field of the Invention

This invention relates generally to spin-electronic devices, more particularly to a method to make a magnetic random access memory using collimated oxygen ion implantation.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, by using a material having a large magnetic crystalline anisotropy, both miniaturization and lower currents can be expected to be achieved while a thermal disturbance resistance is maintained.

There has been a known technique for achieving a high MR ratio in a perpendicular magnetoresistive element by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. However, where a MTJ is formed as a device of a perpendicular magnetization type, the materials of the recording layer typically used in an in-plane MTJ for both high MR and low damping constant as required by low write current application normally don't have enough magnetic crystalline anisotropy to achieve thermally stable perpendicular magnetization against its demagnetization field. In order to obtain perpendicular magnetization with enough thermal stability, the recording layer has to be ferromagnetic coupled to additional perpendicular magnetization layer, such as TbCoFe, or CoPt, or multilayer such as (Co/Pt)n, to obtain enough perpendicular anisotropy. Doing so, reduction in write current becomes difficult due to the fact that damping constant increases from the additional perpendicular magnetization layer and its associated seed layer for crystal matching and material diffusion during the heat treatment in the device manufacturing process.

In a spin-injection MRAM using a perpendicular magnetization film, a write current is proportional to the perpendicular anisotropy, the damping constant and inversely proportional to a spin polarization, and increases in proportional to a square of an area size. Therefore, reduction of the damping constant, increase of the spin polarization and reduction of an area size are mandatory technologies to reduce the write current.

Besides a write current, the stability of the magnetic orientation in a MRAM cell as another critical parameter has to be kept high enough for a good data retention, and is typically characterized by the so-called thermal factor which is proportional to the perpendicular anisotropy as well as the volume of the recording layer cell size. Although a high perpendicular anisotropy is preferred in term of a high thermal disturbance resistance, an increased write current is expected as a cost.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ. Majorities of cell-to-cell variations come from the MTJ cell patterning process.

The conventional fabrication method to form STT-MRAM is by etching and dielectric refilling. During the fabrication magnetic random access memory, reactive ion etching (RIE) is often used to etch away the surrounding materials outside the photoresist protected region. To etch the magnetic materials, the so-called magnetic etchant gas, methanol (CH₃OH), ethanol (C₂H₅OH) and propanol (C₃H₇OH) (used in Anelva etching tool—see U.S. Pat. No. 7,060,194) or CO & NH4 proposed in literature many years ago are often used. Although a nice device junction could be obtained, there often exist dead layers (140) surrounding the device cell (120) as indicated the dark region in FIG. 1, in which all magnetic property is lost but electrically still conducting. Such dead layer inevitably will result in current shunting, and thus reduce DR/R signal of the device. For the production of MRAM device, such dead layer should be avoided or repaired as much as possible.

Thus, it is desirable to provide a greatly improved method or innovative method that enables well-controllable and low cost fabrication in MTJ patterning while eliminating damage, degradation and corrosion.

### BRIEF DESCRIPTION OF THE DRAWINGS

FIG. 1 Sidewall damaged MRAM cell.

FIG. 2 MRAM cross section showing oxygen-gettering material already implanted surrounding the photo mask opened areas.

FIG. 3 MRAM cross section after oxygen implantation showing an oxidization layer surrounding the photo mask opened areas.

FIG. 4 The formed MRAM cell with metal oxide dielectric layer surrounding the MRAM cell.

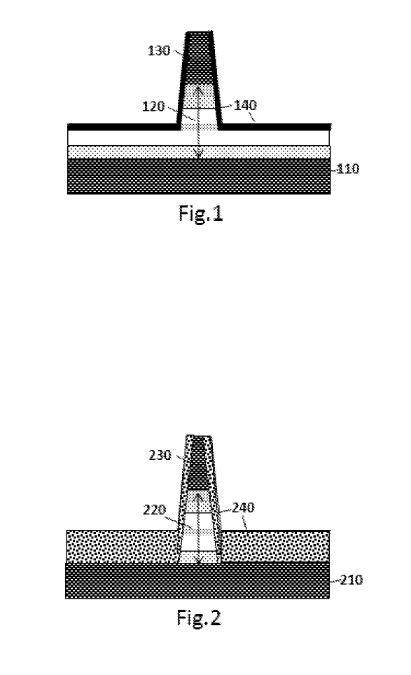

### BRIEF SUMMARY OF THE PRESENT INVENTION

A Method to form small magnetic random access memory (MRAM) by dual ion implantation is provided. The first ion implantation add oxygen-gettering material surrounding the photo mask opened areas including sidewall followed by oxygen ion implantation to fully oxidize these oxygen-getter implanted areas into an electrically insulating layers to avoid current shunting during memory read/write time, and thus maximizing the tunneling magnetic resistance (TMR) signal. Such method is effective to repair the magnetic dead (weak or non magnetic but electrically conducting) layer on the sidewall.

### DETAILED DESCRIPTION OF THE INVENTION

In this invention, we propose to do dual ion implantation to cure magnetic dead layer problem. After the photolithography patterning and top layers etch by RIE, we carry out the first ion implantation using oxygen gettering material selected among Mg, Zr, Y, Th, Ti, Al, Ba to add it into the exposed areas (240) both in the plane and on the sideway as indicated by the dotted region in FIG. 2, which cover the bottom seed layer (210), core device region (220) and top etching stop layer (230). To add more oxygen getter ions into the side wall, the ion bean can tilted.

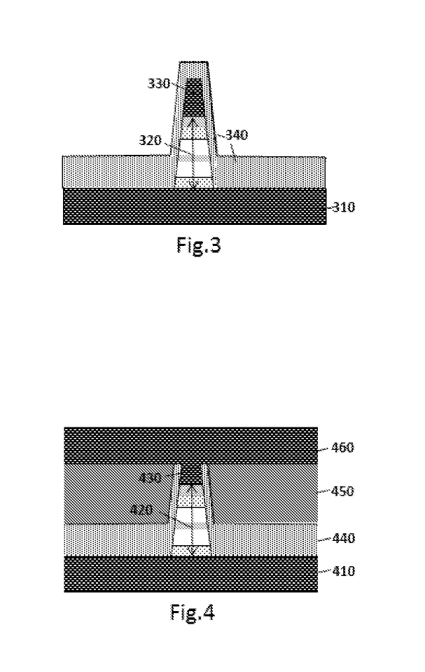

Right after the first oxygen—getter implantation process, a second ion implantation is used to add oxygen into the first implanted region. Due to the high oxygen activity of these oxygen gettering materials, after a high temperature anneal, the dual ion implanted region are easily converted into an electrically insulating dielectric matrix (340 in FIG. 3), thus forming a well defined dielectric boundary outside the central memory region (320).

Finally, another dielectric film such as SiO2, SiNx, Al2O3 is refilled in the upper etched region. After a chemical mechanic polish (CMP), the flattened top surface is deposited with a metallic layer such as Ru, Ta/Ru/Ta to form top electrical lead (460) after another photolithography patterning and etch shown in FIG. 4, in which the wide wall dead layer has been completely converted into a metal oxide layer and become part of the insulating matrix (440 & 450).

1. An integrated circuit electronic device is created by dual ion implantation.

2. The element of claim 1, wherein said integrated circuit electronic device is a magnetic random access memory (MRAM).

3. The element of claim 1, wherein said MRAM is a spin transfer torque magnetic random access memory (STT-MRAM), to be more specific, a perpendicular spin torque transfer magnetic random access memory (pSTT-MRAM).

4. The element of claim 3, wherein said MRAM contains an ion implantation stopping layer, an oxygen gettering layer, an active device layer, an ion-capping layer, and ion-mask layer.

5. The element of claim 4, wherein said oxygen ion stopping layer is Hf, Ta, W, Re, Os, Ir, Pt, Au with a thickness between 200 A to 500 A, and preferably to be Pt or Au for their oxidation resistance.

6. The element of claim 4, wherein said oxygen gettering material is Mg, Zr, Y, Th, Ti, Al, Ba with a thickness between 20 A to 100 A, and preferably to be Mg for MRAM device due to its close lattice match with CoFe and CoFeB.

7. The element of claim 3, wherein said pSTT-MRAM contains a CoFeB memory layer with a thickness between 10-30 A, a MgO dielectric tunneling layer with a thickness between 8-15 A and magnetic reference layer of CoPt, CoPd, CoTb, FePt, FePd, FeTb or [CoFe/Ni]n, [Co/Pt]n, [Co/Pd]n, [Fe/Pt]n, [FePd]]n multilayer with a total thickness between 30 A to 80 A.

8. The element of claim 4, wherein said ion-capping layer is Ru, Cu, Al, Cr with a thickness between 100 A-300 A, and preferably to be Ru for MRAM device.

9. The element of claim 4, wherein said MRAM film stack in is photolithography patterned, and subsequently the ion-mask is etched.

10. The element of claim 9, wherein said ion-mask is Ta and the etchant gas is CF4 or CF3H or other C,F,H containing gases.

11. The element of claim 9, wherein said etch is stopped in the middle MgO dielectric layer, or at the bottom memory layer.

12. The element of claim 9, wherein said remaining photoresist and redep is removed by oxygen burning.

13. The element of claim 12, wherein said patterned IC device undergoes the first ion implantation by oxygen gettering material selected from Mg, Zr, Y, Th, Ti, Al, Ba.

14. The element of claim 13, wherein said oxygen getter ion beam is tilted to add more oxygen gettering material into the side wall.

15. The element of claim 14, wherein said patterned IC device is undergone a second oxygen ion implantation.

16. The element of claim 15, wherein said patterned IC device is refilled with SiO2, SiNx, or AlOx dielectrics.

17. The element of claim 16, wherein said dielectric filled device wafer is chemical mechanical polished to flatten the surface and remove the top portion of the oxidized ion-mask.

18. The element of claim 17, wherein said CMP flattened device wafer is deposited with a metallic electrode layer made of Ru, Cu, Al or alloy of them or sandwiched between two Ta layers, Ta/Ru/Ta or Ta/Cu&Al alloy/Ta, with a thickness of 500 to 1000 A.

19. The element of claim 18, wherein said top electrode layer is patterned and etched to form electrode line.

20. The element of claim 19, wherein said integrated circuit device wafer is high-temperature annealed between 250° C. to 500° C. for 30 seconds to 30 minutes to activate the metal-oxide bonding and to repair the device damage during oxygen ion implantation.
